(19) United States
(12) Patent Application Publication
(10) Pub. No.: US 2009/0262424 A1
(43) Pub. Date: Oct. 22, 2009

(54) DISPLAY SCREEN ASSEMBLY

(75) Inventors: ZHENG SHI, Shenzhen City (CN); CHIH-CHIANG CHANG, Shindian (TW)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/184,326

(22) Filed: Aug. 1, 2008

(30) Foreign Application Priority Data
Apr. 22, 2008 (CN) 200810301243.3

(51) Int. Cl. H05K 5/00; G02B 23/16

(52) U.S. Cl. 359/513; 361/679.01

(57) ABSTRACT

The invention discloses a display screen assembly (30) which includes a display screen (31), an adhesive layer (33), an airproof gasket (35), a non-adhesive protective film (36) and a single adhesive protective film (38). The display screen (31) includes a display surface (311), and the airproof gasket (35) is adhered on the display surface (311) of the display screen (31) by the adhesive layer (33). The single adhesive protective film (38) is adhered upon the airproof gasket (35). The non-adhesive protective film (36) is assembled between the single adhesive protective film (38) and the airproof gasket (35) to avoid the single adhesive protective film (38) contacting with the display surface (311) of the display screen (31).

### BACKGROUND OF THE INVENTION

1. Technical field

The present invention generally relates to a display screen assembly, particularly to a replaceable display screen assembly mounted to a portable electronic device, such as a mobile phone or personal digital assistant (PDA).

2. Discussion of the Related Art

With the development of wireless communication and information processing technology, portable electronic devices such as mobile phones and personal digital assistants (PDAs) are now in widespread use. Consumers may now enjoy the full convenience of high technology products almost anytime and anywhere. Each of these portable electronic devices generally includes a shell and a display screen assembly. The shell defines a display screen window therein. The display screen assembly is replaceablely assembled within the display screen window of the shell of the portable electronic device.

A typical replaceable display screen assembly generally includes a display screen, an airproof gasket and a single adhesive protective film. The display screen has a display surface that adhered with the airproof gasket by an adhesive layer. The single adhesive protective film is adhered upon the airproof gasket to prevent dust from entering into the display screen. However, the adhesive layer of the single adhesive protective film may often contact the display screen causing blots formed on the display screen during the assembled process of replaceable display screen assembly.

Therefore, a new replaceable display screen assembly is desired in order to overcome the above-described shortcoming.

### BRIEF DESCRIPTION OF THE DRAWING

Many aspects of the present display screen assembly can be better understood with reference to the following drawings. The components in the drawings are not necessarily drawn to scale, the emphasis instead being placed upon clearly illustrating the principles of the present display screen assembly. Moreover, in the drawings, like reference numerals designate corresponding parts throughout the several views.

FIG. 1 shows a disassembled, perspective view of the display screen assembly, in accordance with an exemplary embodiment of the present invention.

FIG. 2 is a sectional view of the assembled display screen assembly.

### DETAILED DESCRIPTION OF THE EMBODIMENT

The exemplary embodiment discloses a display screen assembly 30 which is replaceablely mounted on a portable electronic device, such as mobile phone, personal digital assistant (PDA), and so on.

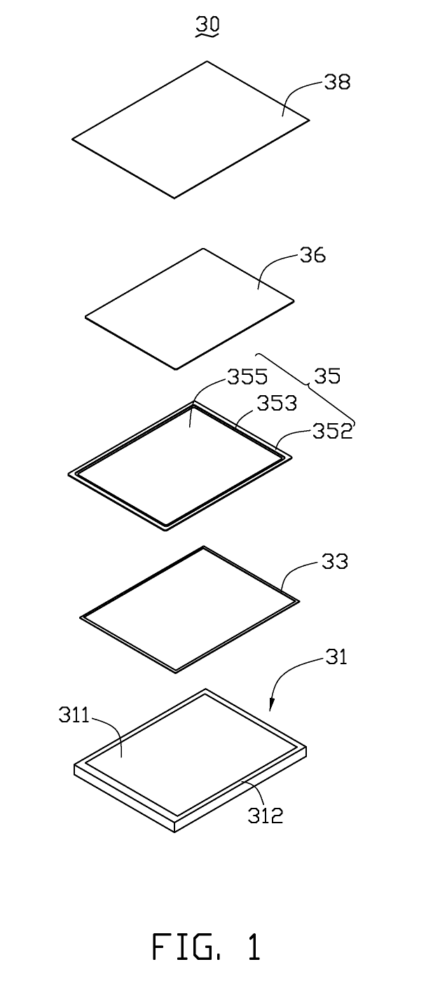

Referring now to the drawings in detail, FIG. 1 shows a disassembled, perspective view of the display screen assembly 30. The display screen assembly 30 includes a display screen 31, an adhesive layer 33, an airproof gasket 35, a non-adhesive protective film 36 and a single adhesive protective film 38. The display screen 31 is substantially rectangular, and has a display surface 311 for displaying information. The display surface 311 includes a first closed rectangular frame 312 surrounding the display surface 311. An adhesive is applied on the first closed rectangular frame 312. The adhesive layer 33 could be a double-sided adhesive layer. The airproof gasket 35 is a substantially rectangular frame and, includes a display window 355 and a second closed rectangular frame portion 352 surrounding the display window 355. In the present embodiment, the surface of the second frame portion 352 facing the display window 355 defines a rectangular, stepped wall 353 thereof for forming a concaved rectangular assembling space (not labeled in the FIG. 1).

The airproof gasket 35 has a shape and size corresponding to the size and shape of the first frame portion 312 so the airproof gasket 35 can be fittingly adhered to the first frame portion 312 by adhesive layer 33. The non-adhesive protective film 36 has a shape and size corresponding to the size and shape of the assembling space of the second frame portion 352. Thus, the non-adhesive protective film 36 can be fittingly assembled in the assembling space of the second frame portion 352. The non-adhesive protective film 36 is made of flexible and transparent material such as polyethylene terephthalate (PET). The single adhesive protective film 38 has a shape and size corresponding to the size and shape of the airproof gasket 35. Thus, the single adhesive protective film 38 can be fittingly mounted on the second frame portion 352 to prevent dust from entering into the display screen 31 and contaminating the display screen 31.

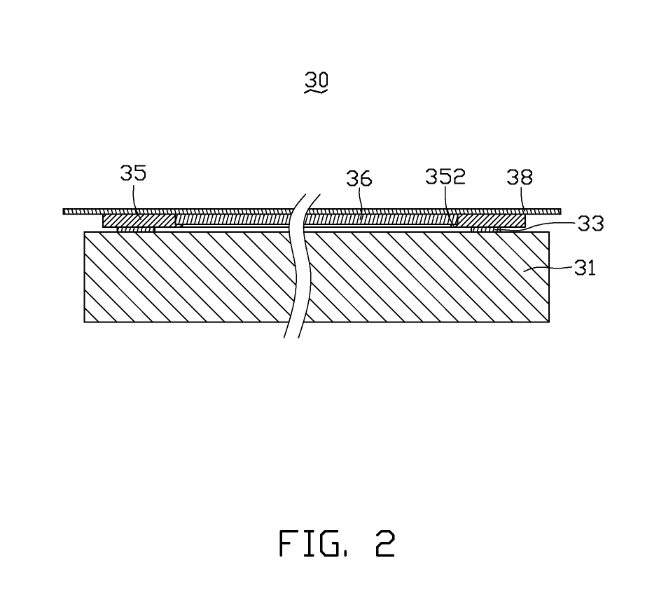

Also referring to FIG. 2, in assembly, the airproof gasket 35 is adhered on the first frame portion 312 by adhesive layer 33. The non-adhesive protective film 36 is fittingly assembled in the assembling space of the second frame portion 352. The single adhesive protective film 38 is fittingly mounted on the second frame portion 352.

The non-adhesive protective film 36 is mounted between the protective film 38 and the airproof gasket 35, thus preventing the single adhesive protective film from contacting with the display surface 311. As a result, the present display screen assembly 30 avoids blots formed on the display surface 311, to assure and enhance the display effect and quality.

Finally, it is to be understood, however, that even though numerous characteristics and advantages of the present invention have been set forth in the foregoing description, together with details of the structure and function of the present invention, the disclosure is illustrative only, and changes may be made in detail, especially in matters of shape, size, and arrangement of parts within the principles of present invention to the full extent indicated by the broad general meaning of the terms in which the appended claims are expressed.

What is claimed is:

1. A display screen assembly mounted to a portable electronic device, comprising:
a display screen which includes a display surface;
an adhesive layer;
an airproof gasket adhered on the display surface by the adhesive layer;
a single adhesive protective film; and
a non-adhesive protective film assembled between the single adhesive protective film and the airproof gasket to prevent the single adhesive protective film from contacting the display surface.

2. The display screen assembly as claimed in claim 1, wherein the display surface includes an first frame portion surrounding the display surface for an adhesive to be applied thereon; the airproof gasket includes a display window and a second frame portion surrounding the display window, and the airproof gasket is adhered on the first frame portion of the display surface of the display screen with the adhesive layer.

3. The display screen assembly as claimed in claim 2, wherein the surface of the second frame portion facing the display window defines a rectangular, stepped wall or forming a concaved assembling space; the non-adhesive protective film is fittingly assembled in the assembling space of the second frame portion.

4. The display screen assembly as claimed in claim 3, wherein the airproof gasket has a shape and size corresponding to that of the first frame portion of the display screen.

5. The display screen assembly as claimed in claim 3, wherein the non-adhesive protective film has a shape and size corresponding to the size and shape of the assembling space.

6. The display screen assembly as claimed in claim 1, wherein the non-adhesive protective film is made of a flexible, transparent material.

7. The display screen assembly as claimed in claim 6, the non-adhesive protective film is made of polyethylene terephthalate.

8. The display screen assembly as claimed in claim 1, wherein the adhesive layer is a double-sided adhesive layer.

9. A display screen assembly mounted to a portable electronic device, comprising:
a display screen which includes a display surface;
an airproof gasket which is adhered on the display surface of the display screen by adhesive;
a single adhesive protective film; and
a non-adhesive protective film which is assembled between the single adhesive protective film and the airproof gasket to prevent the single adhesive protective film contacting with the display surface of the display screen.

10. The display screen assembly as claimed in claim 9, wherein the display surface includes an first frame portion surrounding the display surface for an adhesive be applied thereon; the airproof gasket includes a display window and a second frame portion surrounding the display window, and the airproof gasket is adhered on the first frame portion of the display surface of the display screen with the adhesive.

11. The display screen assembly as claimed in claim 10, wherein one surface of the second frame portion that facing to the display window defines a rectangular, stepped wall thereof for forming a concaved assembling space; the non-adhesive protective film is fittingly assembled in the assembling space of the second frame portion.

12. The display screen assembly as claimed in claim 11, wherein the airproof gasket has a shape and size corresponding to the size and shape of the first frame portion of the display screen.

13. The display screen assembly as claimed in claim 11, wherein the non-adhesive protective film has a shape and size corresponding to the size and shape of the assembling space of the frame portion of the airproof gasket.

14. The display screen assembly as claimed in claim 9, wherein the non-adhesive protective film is made of a flexible, transparent material.

15. The display screen assembly as claimed in claim 14, the non-adhesive protective film is made of polyethylene terephthalate.
